(19) United States
(12) Patent Application Publication
(10) Pub. No.: US 2012/0268910 A1
(43) Pub. Date: Oct. 25, 2012

(54) PIEZOELECTRIC VIBRATOR WITH DOUBLE-ENDED SHAFT SUPPORT

(76) Inventors: Albert J. Golko, Saratoga, CA (US); Eric N. Nyland, London (CA)

(21) Appl. No.: 13/090,612

(22) Filed: Apr. 20, 2011

(51) Int. Cl. H02N 2/12; H05K 7/02; H02K 7/075

(52) U.S. Cl. 361/807; 310/81; 310/323.02

(57) ABSTRACT

An electronic device may be provided with a vibrator. The vibrator may vibrate to alert a user to an incoming cellular telephone call or other events. The vibrator may have a piezoelectric vibrator motor. The piezoelectric vibrator motor may rotate a shaft about a rotational axis. A weight may be attached to the shaft so that the vibrator vibrates when the shaft is rotated. The shaft may have opposing first and second ends. To help prevent damage to the vibrator during a drop event, the first and second ends of the shaft may be supported by support structures and end caps or other structures for retarding axial movement may be provided. The support structures may be formed from a bracket having vertical members with holes that respectively receive the first and second ends. The stop structures may prevent movement of the shaft along its rotational axis.

### BACKGROUND

This relates generally to vibrators, and, more particularly, to vibrators for electronic devices.

Electronic devices such as cellular telephones are often provided with vibrators. A vibrator may be used to alert a user to an incoming telephone call or other activity.

Conventional vibrators are formed from electric motors. A rotationally unbalanced weight is affixed to the protruding end of a motor shaft. As the shaft rotates around a rotational axis, the vibrator and the device to which the vibrator is mounted will vibrate.

Electronic devices such as cellular telephones and other portable electronic devices may sometimes be accidentally dropped. During a drop event, axial movement of the weight and the motor shaft may cause damage to the vibrator.

It would therefore be desirable to provide improved vibrators for electronic devices.

### SUMMARY

An electronic device may be provided with a vibrator. The vibrator may vibrate to alert a user to an incoming cellular telephone call or other events.

The vibrator may have a compact piezoelectric vibrator motor. Piezoelectric elements in the vibrator motor may be driven using a drive circuit to cause the vibrator motor to rotate a shaft about a rotational axis.

A weight may be attached to the shaft so that the vibrator vibrates when the shaft is rotated. The shaft may have opposing first and second ends. To help prevent damage to the vibrator during a drop event, the first and second ends of the shaft may be supported by support structures and stop structures such as end caps may be formed on the ends of the shaft. The support structures may be formed from a bracket having vertical members with holes that respectively receive the first and second ends. Bearings may be placed in the holes. The stop structures that are mounted to the first and second ends of the shaft may prevent longitudinal movement of the shaft along its rotational axis, thereby spreading impact loads among the support structures and helping the vibrator to withstand damage from a drop event. The stop structures may be formed from members that are press fit onto the first and second ends of the shaft, from c-rings that are mounted within grooves on the shaft, from members that are welded to the ends of the shaft, from portions of the shaft that have been deformed, or other structures.

The vertical members of the bracket may be mounted to a common horizontal member. The horizontal member may have an opening to accommodate movement of the weight about the rotational axis without striking the bracket.

Further features of the invention, its nature and various advantages will be more apparent from the accompanying drawings and the following detailed description of the preferred embodiments.

### BRIEF DESCRIPTION OF THE DRAWINGS

FIG. 1 is a perspective view of an illustrative electronic device of the type that may include a vibrator in accordance with an embodiment of the present invention.

FIG. 2 is a perspective view of an illustrative vibrator motor that includes piezoelectric elements in accordance with an embodiment of the present invention.

FIG. 3 is an illustrative bracket for a vibrator motor of the type shown in FIG. 2 in accordance with an embodiment of the present invention.

FIG. 4 is a cross-sectional side view of an illustrative vibrator in accordance with an embodiment of the present invention.

FIG. 5 is a cross-sectional side view of an illustrative vibrator shaft that has portions that have been bent back from the shaft to form a stop structure in accordance with an embodiment of the present invention.

FIG. 6A is a cross-sectional side view of an illustrative vibrator shaft with a stop structure formed from a c-ring in accordance with an embodiment of the present invention.

FIG. 6B shows an illustrative c-ring of the type used in FIG. 6A to form a stop structure on a vibrator shaft in accordance with an embodiment of the present invention.

FIG. 7 is a cross-sectional side view of an illustrative vibrator shaft having a stop structure that is attached to the end of the shaft using welds or other fastening mechanisms in accordance with an embodiment of the present invention.

FIG. 8 is a cross-sectional side view of an illustrative vibrator shaft having a stop structure that is formed from flared portions of a deformed end of a shaft in accordance with an embodiment of the present invention.

FIG. 9 is a perspective view of a vibrator mounting bracket showing how the vibrator mounting bracket may include portions that can be crimped around a shaft in accordance with an embodiment of the present invention.

FIG. 10 is a cross-sectional side view of an illustrative vibrator shaft mounted in a bracket in which a stop structure has been captured between two opposing bracket members in accordance with an embodiment of the present invention.

### DETAILED DESCRIPTION

Electronic devices such as cellular telephones, tablet computers, media players, other portable electronic devices, and other electronic equipment may be provided with vibrators.

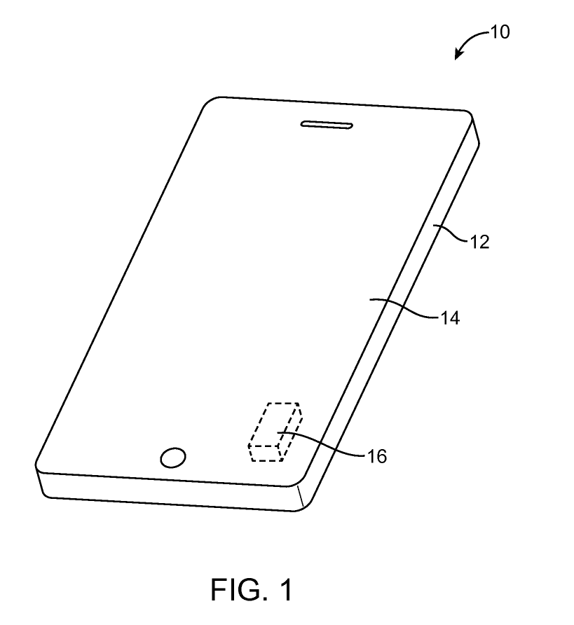

An illustrative electronic device of the type that may be provided with a vibrator is shown in FIG. 1. Electronic device 10 may be a portable electronic device or other suitable electronic device. For example, electronic device 10 of FIG. 1 may be a laptop computer, a tablet computer, a somewhat smaller device such as a wrist-watch device, pendant device, headphone device, earpiece device, or other wearable or miniature device, a cellular telephone, a media player, etc.

Device 10 may include a housing such as housing 12. Housing 12, which may sometimes be referred to as a case, may be formed of plastic, glass, ceramics, fiber composites, metal (e.g., stainless steel, aluminum, etc.), other suitable materials, or a combination of these materials. Device 10 may, if desired, have a display such as display 14. Display 14 may, for example, be a touch screen that incorporates capacitive touch electrodes or other touch sensors. Display 14 may include image pixels formed from light-emitting diodes (LEDs), organic LEDs (OLEDs), plasma cells, electronic ink elements, liquid crystal display (LCD) components, or other suitable image pixel structures.

Components such as integrated circuits, connectors, switches, sensors, speakers, microphones, cameras, and other electronic components may be mounted in housing 12. Vibrator 16 may also be mounted in housing 14. Vibrator 16 may be used to vibrate device 10. For example, vibrator 16 may be used to vibrate device 10 when an alarm timer has expired. Vibrator 16 may also vibrate device 10 when an incoming telephone call is received (e.g., when device 10 has been placed in a silent mode in which audible telephone ringing has been suspended).

Vibrator 16 may be implemented using any suitable vibrator technology. For example, vibrator 16 may include a solenoid, an electric motor, or other electromagnetic device that moves a weight. With one suitable arrangement, which is sometimes described herein as an example, vibrator 16 may be implemented using a vibrator motor that is based on piezoelectric elements.

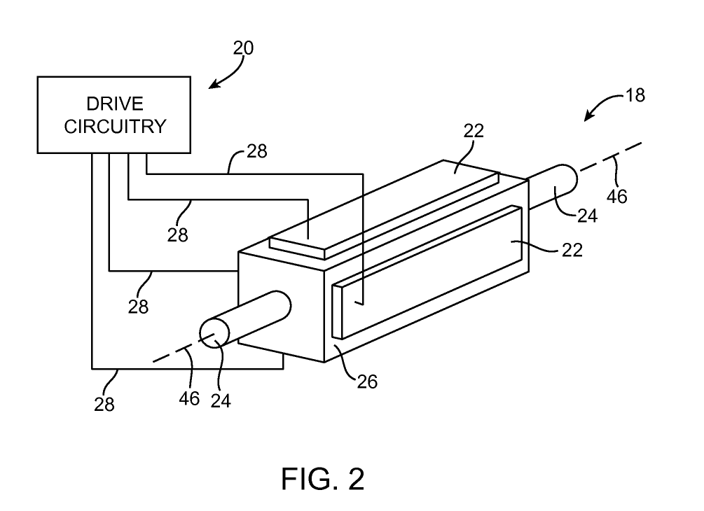

An illustrative vibrator motor that has piezoelectric elements is shown in FIG. 2. As shown in FIG. 2, vibrator motor 18 may have piezoelectric elements 22 mounted on main body member 26. With one suitable arrangement, there may be four of piezoelectric elements 22, each mounted on one of the four sides of body member 26 (e.g., on the left and right sides and the top and bottom sides in the orientation of FIG. 2). Arrangements with different numbers of piezoelectric elements (e.g., fewer than four or more than four) and arrangements in which piezoelectric elements are located in different positions relative to shaft 24 and body member 26 may be used if desired. The arrangement of FIG. 2 is merely illustrative.

Drive circuitry 20 may be used to provide piezoelectric elements 22 with control signals over control paths 28. These control signals may control the shape of each piezoelectric element. Shaft 24 may run through the center of body member 26. Shaft 24 and body member 26 may include interlocking features (e.g., threads), so that shaft 24 rotates when piezoelectric elements 22 are driven using appropriate drive signals on paths 28.

Shaft 24 of vibrator motor 18 may have two exposed ends. A rotationally asymmetric weight may be formed on one or both ends of shaft 24, so that vibrations are induced when shaft 24 is rotated about rotational axis 46 by vibrator motor 18.

To prevent damage to shaft 24 of vibrator motor 18 when device 10 is accidentally dropped, it may be desirable to support both of the opposing ends of shaft 24 and to form stop structures on each of the opposing ends. Any suitable mounting structure that supports both ends of shaft 34 may be used if desired (e.g., metal support structures, plastic support structures, bearings, parts of electronic device housing structures, etc.). As shown in FIG. 3, for example, vibrator motor mounting bracket 30 may have shaft support openings such as openings 32 in vertical end wall structures 38. Openings 32 may receive shaft 24. Each opening 32 may be used to support a respective end of shaft 24. Openings 32 may be sized to receive shaft 24 directly or may be oversized to accommodate bearings (e.g., sleeve bearings or ball bearings that surround and support shaft 24, etc.).

Vertical wall structures 38 of bracket 30 may be mounted on horizontal bracket base structure 36. Base structure 36 may be mounted within housing 12 using adhesive, screws, welds, or other fastening mechanism. An opening such as opening 34 may be formed in bracket base structure 36 to accommodate a rotating weight mounted on shaft 24.

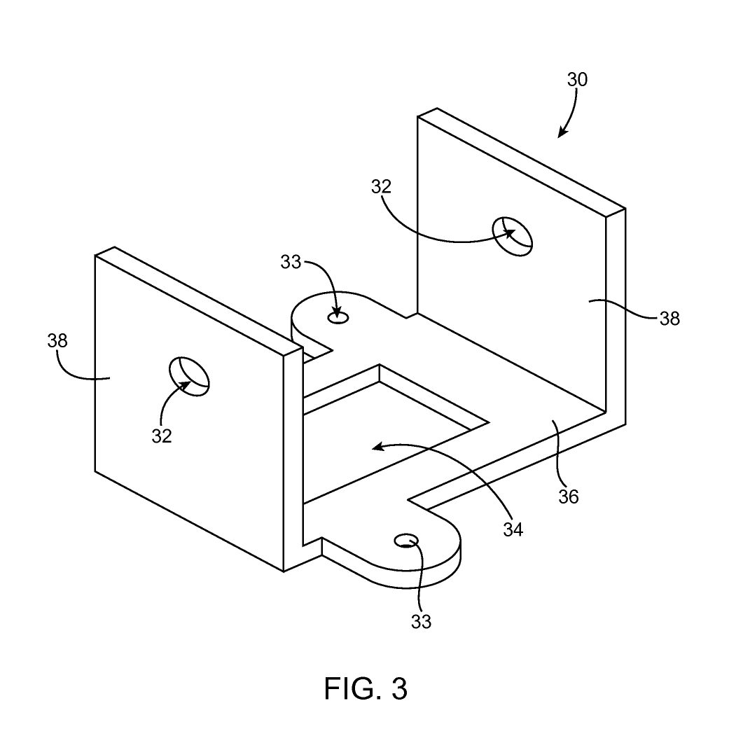

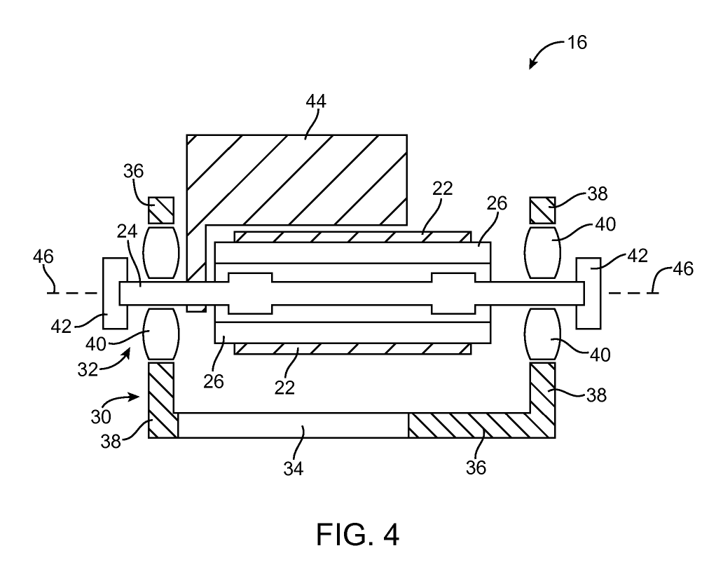

A cross-sectional side view of a vibrator that includes a vibrator motor mounted in support structures such as mounting bracket 30 of FIG. 3 is shown in FIG. 4. As shown in FIG. 4, vibrator 16 may have a weight such as weight 44 that is mounted on shaft 24. As shaft 24 rotates around rotational axis 46, weight 44 rotates about axis 46 and shaft 24. An opening such as opening 34 may be provided in bracket 30 to allow weight 44 to rotate under shaft 24 without striking bracket 30. This type of arrangement allows vibrator 16 to be implemented in a low-height configuration. If desired, the height of end wall members 36 can be increased to prevent weight 44 from striking portion 36 of bracket 30.

The rotation of weight 44 causes vibrator 16 to vibrate. Vibrations from vibrator 16 are conveyed to device 10 via mounting bracket 30. Because both ends of shaft 24 are supported by bracket 30, vibrations may be transmitted efficiently from vibrator 16 to housing 12 of device 10.

In the example of FIG. 4, optional bearings 40 have been inserted into holes 32. Shaft 24 may be supported by bearings 40. Bearings 40 may be sleeve bearings, ball bearings, or bearings of other types. Stop structures 42 have been formed on both ends of shaft 24 to prevent longitudinal movement of shaft 24 (i.e., to prevent movement of shaft 24 parallel to axis 46). Stop structures 42 may be press-fit members that are press fit over the ends of shaft 24 or may be members that are attached to shaft 24 using other suitable attachment mechanisms (e.g., welds, adhesive, screws, etc.). Stop structures 42 may also be formed by locally deforming portions of shaft 24. Bearings 40, bracket 30, shaft 24, and stop structures 42 may be formed from metal, plastic, or other materials. The support that is provided to both ends of shaft 24 by bracket 30 and the ability to resist axial movement that is provided by each of the associated stop structures 32 may help prevent damage to vibrator 16 in a drop event. If, for example, vibrator 16 were to be dropped on one of its shaft ends, the stop structure on the other end of the shaft would help dissipate some of the axial force generated by the impact, thereby helping to prevent damage.

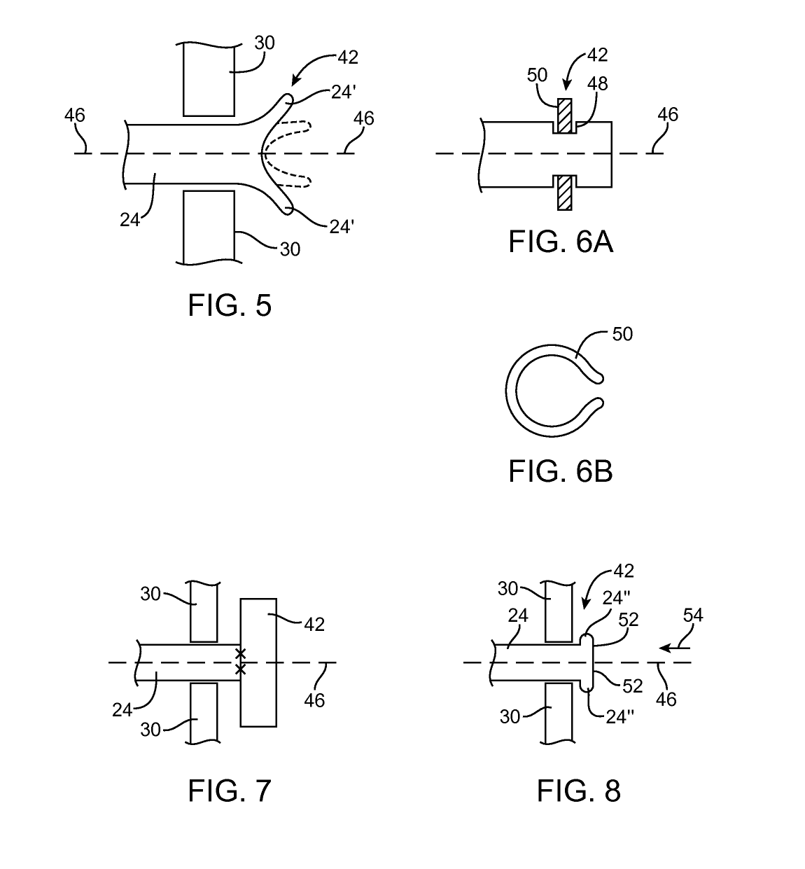

If desired, stop structures 42 may be formed by bending a portion of the end of shaft 24. As shown in FIG. 5, for example, portions 24′ of shaft 24 may be flared outwards away from axis 46 to form stop structures 42.

In the illustrative arrangement of FIG. 6A, the end of shaft 24 has been provided with circumferential groove 50 and mating c-ring 50. When c-ring 50 is attached to shaft 24 in groove 48, c-ring 50 forms stop structures 42. FIG. 6B is a front view of c-ring 50.

As shown in the cross-sectional side view of shaft 24 in FIG. 7, stop structures 42 may be attached to the end of shaft 24 using attachment features 52. Attachment features 52 may include adhesive, welds, solder, or other suitable attachment mechanisms.

FIG. 8 is a cross-sectional side view of an illustrative configuration for shaft 24 showing how stop structures 42 may be formed by pressing inwardly on the end of shaft 24 in direction 54 to deform shaft 24. The pressure on the end of shaft 24 flattens end portion 52 and creates protruding portions 24″ that serve as stop structures 42.

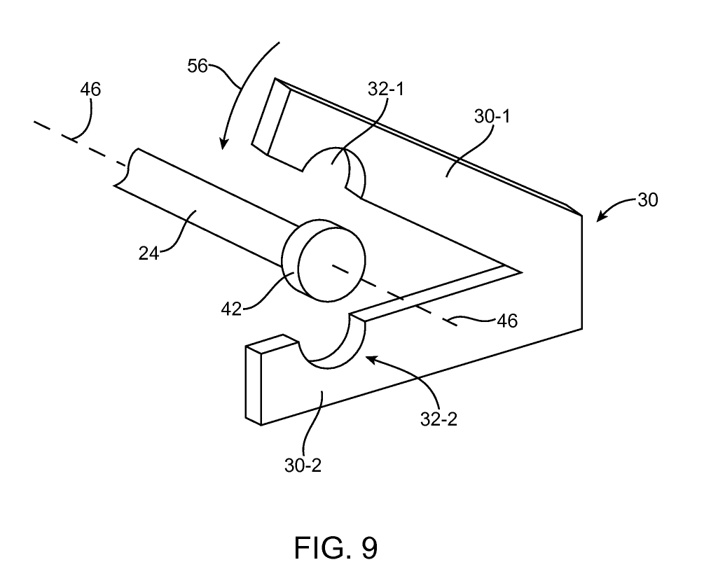

If desired, stop structures 42 may be formed on the ends of shaft 24 FIG. 9 before shaft 24 is mounted in bracket 30. To accommodate this order of assembly, bracket 30 may be provided with a shape that allows bracket 30 to be crimped over the end of shaft 24 after stop structures 42 have been formed. As shown in FIG. 9, for example, bracket 30 may have upper bracket portion 30-1 and lower bracket portion 30-2. Portion 30-1 may have an opening such as hemispherical opening 32-1, whereas portion 30-2 may have an opening such as hemispherical opening 32-2. Bracket 30 may initially have an open-jaw shape of the type shown in FIG. 9. After positioning shaft 24 as shown in FIG. 9, upper portion 30-1 may be bent downward in direction 56 so that portion 30-1 mates with portion 30-2. In this configuration, hole portions 32-1 and 32-1 will form a circular hole (hole 32) that surrounds shaft 24. Stop structures 42 on the ends of shaft 24 will then prevent longitudinal movement of shaft 24 along axis 46.

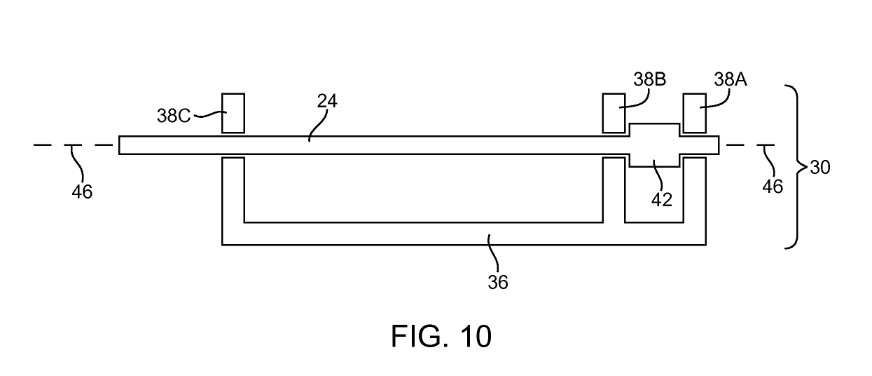

As shown in FIG. 10, mounting bracket 30 may have vertical portions that are located on opposing sides of a single stop member. In the FIG. 10 example, mounting bracket 30 has three vertical structures (vertical structure 38A, vertical structures 38B, and vertical structure 38C) mounted on a common base structure (base structure 36). Structure 38C may be used to support the left-hand end of shaft 24, but need not be provided with a stop structure. Stop structure 42 (e.g., a press-fit disk, a c-ring structure, deformed portions of shaft 24, etc.) may be formed on shaft 24 near the right-hand end of shaft 24 and may be captured between opposing vertical structures 38A and 38C to prevent movement of shaft 24 along rotational axis 46.

In the FIG. 10 example, the left-hand end of shaft 24 is supported by a single vertical bracket structure and the right-hand end of shaft 24 is supported using dual vertical bracket structures. If desired, both the left-hand and right-hand ends of shaft 24 may be supported by dual vertical bracket structures. The FIG. 10 arrangement is merely illustrative.

The foregoing is merely illustrative of the principles of this invention and various modifications can be made by those skilled in the art without departing from the scope and spirit of the invention. The foregoing embodiments may be implemented individually or in any combination.

What is claimed is:

1. A vibrator, comprising:
a vibrator motor having a shaft with first and second ends;
a weight attached to the shaft so that the vibrator vibrates when the shaft is rotated; and
vibrator motor mounting structures having a first portion that receives and supports the first end of the shaft and having a second portion that receives and supports the second end of the shaft.

2. The vibrator defined in claim 1 wherein the first portion comprises a first hole through which the first end of the shaft protrudes and wherein the second portion comprises a second hole through which the second end of the shaft protrudes.

3. The vibrator defined in claim 2 further comprising bearings in the first and second holes.

4. The vibrator defined in claim 2 further comprising stop structures on the first and second ends of the shaft.

5. The vibrator defined in claim 4 wherein the stop structures comprise respective first and second press-fit members on the first and second ends of the shaft.

6. The vibrator defined in claim 4 wherein the stop structures comprise first and second locally deformed portions of the shaft.

7. The vibrator defined in claim 4 wherein the stop structures comprise respective first and second c-rings that are each attached to a respective groove in the shaft.

8. The vibrator defined in claim 2 wherein the vibrator motor mounting structures further comprises a third portion having a third hole through which the shaft passes, the vibrator further comprising stop structures on the shaft that are interposed between the third and second portions of the vibrator motor mounting structures to prevent longitudinal movement of the shaft along its rotational axis.

9. A vibrator, comprising:
a piezoelectric motor having a shaft, wherein the shaft rotates about a rotational axis and has first and second ends;
a weight attached to the shaft so that the vibrator vibrates when the shaft is rotated about the rotational axis; and
support structures having a first hole that receives the first end of the shaft and having a second hole that receives the second end of the shaft.

10. The vibrator defined in claim 9 wherein the support structures comprise a bracket.

11. The vibrator defined in claim 10 wherein the bracket has a first vertical member and a second vertical member attached to a horizontal member.

12. The vibrator defined in claim 11 wherein the first hole is formed in the first vertical member and receives the first end of the shaft and wherein the second hole is formed in the second vertical member and receives a second end of the shaft.

13. The vibrator defined in claim 12 wherein the horizontal member has an opening that allows the weight to rotate about the rotational axis without striking the bracket.

14. The vibrator defined in claim 12 further comprising stop structures on the first and second ends that prevent movement of the shaft with respect to the bracket parallel to the rotational axis.

15. The vibrator defined in claim 14 wherein the stop structures are attached to the first and second ends with welds.

16. The vibrator defined in claim 14 wherein the stop structures are press fit onto the ends.

17. The vibrator defined in claim 14 wherein the stop structures include at least one structure that is mounted in a groove in the shaft.

18. A portable electronic device, comprising:
a housing; and
a vibrator mounted to the housing, wherein the vibrator includes:
a piezoelectric motor having a shaft, wherein the shaft rotates about a rotational axis and has first and second ends;
a weight attached to the shaft so that the vibrator vibrates when the shaft is rotated about the rotational axis; and
support structures that support the first and second ends of the shaft and that are mounted to the housing.

19. The portable electronic device defined in claim 18 wherein the support structures comprise first and second metal members with respective first and second holes that respectively receive the first and second ends of the shaft.

20. The portable electronic device defined in claim 19 further comprising structures attached to the first and second ends that prevent movement of the shaft relative to the support structures along the rotational axis.
